(19) United States
(12) Patent Application Publication
(10) Pub. No.: US 2002/0174950 A1
(43) Pub. Date: Nov. 28, 2002

(54) Apparatus for manufacturing a semiconductor device

(76) Inventor: Sang-Gee Park, Seoul (KR)

Correspondence Address: LEWIS F. GOULD, JR., DUANE MORRIS LLP, ONE LIBERTY PLACE, PHILADELPHIA, PA, 19103, US

(21) Appl. No.: 10/138,109

(22) Filed: May 3, 2002

(30) Foreign Application Priority Data
May 4, 2001 (KR) 2001-24233

(51) Int. Cl. C23F 1/00; C23C 16/00

(52) U.S. Cl. 156/345.1; 118/728

(57) ABSTRACT

An apparatus for manufacturing a semiconductor device according to the present invention includes a chamber having a gate valve and an outlet, a susceptor within the chamber to hold a wafer thereon, being movable upward and downward, and having a plurality of lift pin holes, wherein each lift pin hole has a hanging part at the upper end, and a plurality of lift pins passing through the plurality of lift pin holes, wherein each lift pin has a hung part at the upper end and a length of the lift pin being longer than that of the lift pin hole, and the upper diameter of the hung part is shorter than the upper diameter of the hanging part and is longer than the lower diameter of the hanging part.

This application claims the benefit of Korean Patent Application No. 2001-24233, filed on May 4, 2001 in Korea, which is hereby incorporated by reference for all purposes as if fully set forth herein.

### BACKGROUND OF THE INVENTION

1. Field of the Invention

The present invention relates to an apparatus for manufacturing a semiconductor device and more particularly, to an apparatus including a lift pin for loading a substrate to be handled within a chamber.

### DISCUSSION OF THE RELATED ART

A development for a new material has been actively performed in the field and diverse large-scale integrated circuit (LSI) such as ultra large-scale integrated circuit (ULSI) has been developed due to a rapid growth of the new material development. That is, because the new material for forming thin films such as an insulating layer, a semiconductor layer and a conductor layer, which constitute a semiconductor device, has been developed widely in the field, the large-scale integrated circuit (LSI) such as the ultra large-scale integrated (ULSI) circuit is available now. The semiconductor devices are generally fabricated by repeated depositing and patterning process. These processes are accomplished in a manufacturing apparatus of the semiconductor device under vacuum condition.

The manufacturing apparatus of the semiconductor device is classified variously according to a purpose. The apparatus generally includes a processing chamber which is an airtight reaction container, a controller which controls surroundings within the chamber, and a gas supplying system which stores source gases and provides the source gases.

FIGS. 1 and 2 show a conventional apparatus for manufacturing a semiconductor device. FIG. 1 is a view of showing a state of loading or unloading a wafer, and FIG. 2 is a view of showing a state on a process. In FIGS. 1 and 2, the apparatus includes a processing chamber 1, a table 8, and a gas injector 6. The processing chamber 1 has a gate valve 2 and an outlet 4, and the upper part of the chamber 1 is dome-shaped. The gate valve 2, which a wafer to be handled comes into and goes out of the processing chamber 1 through, is formed at a wall of the processing chamber 1. The air within the processing chamber 1 is exhausted out of the processing chamber 1 through the outlet 4. And a gas injector 6, which is connected to the gas supplying system (not shown) outside the processing chamber 1, is disposed on the top of the inner surface of the processing chamber 1. A table 8 is also situated within the chamber 1 and the wafer 50 is posited on the table 8.

The table 8 comprises a susceptor 10, a susceptor drive plate 17, a lift pin base 15, and a lift pin drive plate 19. The susceptor 10 is a shape of a circular plate and has a heater 11 inside for applying heat to the wafer 50. Accordingly, a processing speed gets fast and stable results are gained by heating the wafer 50. And also the susceptor 10 has a plurality of lift pin holes 12 and is connected to the susceptor drive plate 17, which is posited outside the processing chamber 1, with the first vertical column 18a. The susceptor drive plate 17 is driven by a motor “M”, and thus the susceptor 10 moves upward and downward. The first vertical column 18a is passing through the lift pin base 15 disposed under the susceptor 10.

The lift pin base 15 has a plurality of lift pins 13 passing through the plurality of lift pin holes 12 thereon. The lift pin base 15 is connected to the lift pin drive plate 19, which is driven by an air cylinder “P” outside the processing chamber 1, with the second vertical column 18b. The second vertical column 18b is going through the susceptor drive plate 17. Therefore, the plurality of lift pins 13 makes a rising and descending move vertically by an air cylinder “P”.

The structure of the table 8 is shown in detail in FIG. 3. A line “A-A” of FIG. 3 corresponds to the bottom side of the chamber 1 of FIG. 1. As shown in FIG. 3, the susceptor 10, which has a plurality of lift pin holes 12, is connected to the susceptor drive plate 17 with the first vertical column 18a, which passes through the lift pin base 15, and the susceptor drive plate 17 is connected to the motor “M”. The lift pin base 15 under the susceptor 10 has the plurality of lift pins 13, and is connected to the lift pin drive plate 19 under the susceptor drive plate 17 with the second vertical column 18b. The lift pin drive plate 19 is connected to the air cylinder “P”, and thus the lift pin drive plate 19 moves by the air cylinder “P”. The plurality of lift pins 13 passes through the plurality of lift pin holes 12.

As stated above, the upper of the chamber 1 is a shape of a dome, which is able to maximize dispersion effect of source gases within the processing chamber 1 and concentrate the heat from the susceptor 10 into the wafer 50. By the way, the region near the gate valve 2 is so sensitive that the condition such as a temperature and a pressure can change easily in the region. On the other hand, the first region 20a inside the processing chamber 1, which is disposed over the gate valve 2, has stable surroundings than the second region 20b, which is a lower region of the first region 20a. Therefore, it is desirable that depositing a thin film and patterning it are accomplished in the first region 20a.

As the gate valve 2 to transport the wafer 50 through is formed under the first region 20a, the wafer 50 is loaded and unloaded within the second region 20b through the gate valve 2, and the wafer 50 on the susceptor 10 is moved toward the first region 20a. And the depositing or patterning is accomplished in the first region 20a.

At this time, if the susceptor drive plate 17 moves by the motor “M”, the susceptor 10 also moves and if the lift pin drive plate 19 moves by the air cylinder “P”, the lift pins 13 on the lift pin base 15 moves together.

In the meantime, in FIGS. 1 and 2, the first bellows 21 and the second bellows 22 is formed in order to prevent impurities from penetrating into the processing chamber 1, and the first bellows 21 is disposed between the bottom of the chamber 1 and the susceptor drive plate 17, and the second bellows 22 is located between the susceptor drive plate 17 and the lift pin drive plate 19.

First, in the apparatus of FIG. 1, the susceptor 10 and the susceptor drive plate 17 are posited in the second region 20b by the motor “M”, and the plurality of lift pins 13 on the lift pin base 15 rises by the air cylinder “P”. Therefore, the plurality of lift pins 13 protrudes through the plurality of lift pin holes 12 over the susceptor 10. And the wafer 50 is placed on the plurality of lift pins 13. Next, the plurality of lift pins 13 goes down by the air cylinder “P”, and the wafer 50 is loaded on the susceptor 10.

Subsequently, the susceptor 10 ascends with the susceptor drive plate 17 by the motor “M” and the susceptor 10 is posited in the first region 20a as shown in FIG. 2. And source gases from the gas injector 6 is injected into the first region 20a, and so deposition of a thin film is made on the wafer 50 or a thin film on the wafer 50 is patterned. Next, the susceptor 10 having the wafer 50 thereon descends, and is posited in the second region 20b. The plurality of lift pins 13 goes up and raises the wafer 50 over the susceptor 10. And the wafer 50 is taken out of the processing chamber 1 through the gate valve 2.

As the conventional processing chamber should have the lift pin base 15 including the lift pins 13 driven by the air cylinder “P”, the size of the chamber 1 increases. Therefore, it is difficult to control the temperature and pressure within the chamber 1, and so the reliance of the device is lowered. In the conventional processing chamber 1, impurities may occur easily. And also, when the lift pins 13 are broken, the table 8 must be all disassembled, and a cost of the apparatus gets high due to the motor “M” and the air cylinder

### SUMMARY OF THE INVENTION

Accordingly, the present invention is directed to a manufacturing apparatus of a semiconductor device that substantially obviates one or more of problems due to limitations and disadvantages of the related air.

An advantage of the present invention is to provide a manufacturing apparatus of a semiconductor device that a structure is simple and a size is small.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, an apparatus for manufacturing a semiconductor device includes a chamber having a gate valve and an outlet, a susceptor within the chamber to hold a wafer thereon, being movable upward and downward, and having a plurality of lift pin holes, wherein each lift pin hole has a hanging part at the upper end, and a plurality of lift pins passing through the plurality of lift pin holes, wherein each lift pin has a hung part at the upper end and a length of the lift pin being longer than that of the lift pin hole, and the upper diameter of the hung part is shorter than the upper diameter of the hanging part and is longer than the lower diameter of the hanging part.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIGS. 1 and 2 are cross-sectional views of a conventional apparatus for manufacturing a semiconductor device;

FIG. 3 is exploded perspective view of a conventional table including a susceptor;

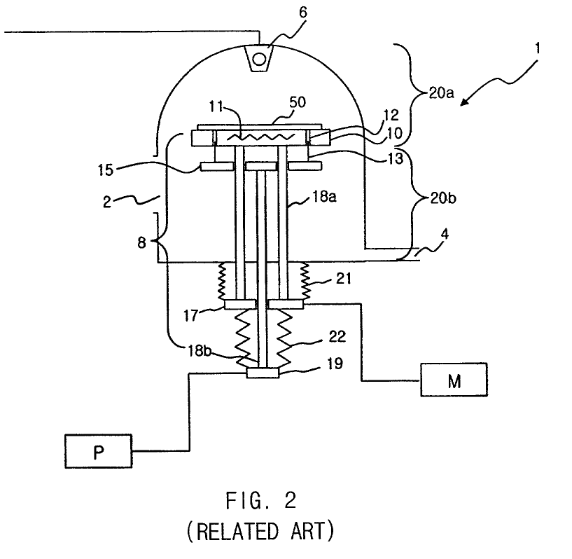

FIG. 4 is a cross-sectional view of an apparatus for manufacturing a semiconductor device according to the present invention

FIGS. 5A and 5B are cross-sectional views of showing structures of the susceptor and the lift pin according to the present invention; and

FIGS. 6A and 6B show processes of driving an apparatus according to the present invention.

### DETAILED DESCRIPTION OF THE ILLUSTRATED EMBODIMENTS

Reference will now be made in detail to the illustrated embodiment of the present invention, which is illustrated in the accompanying drawings.

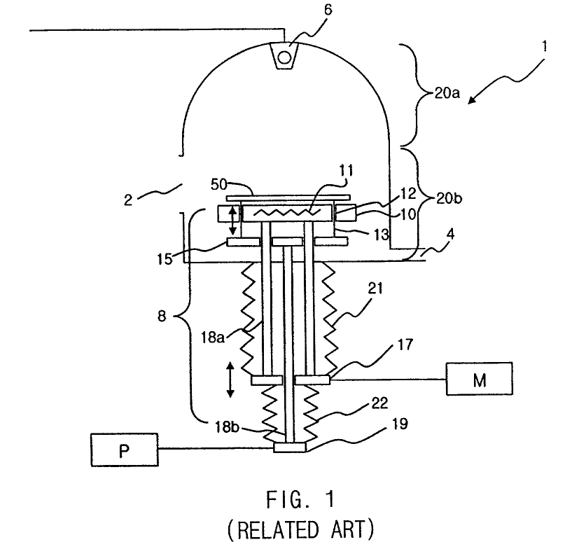

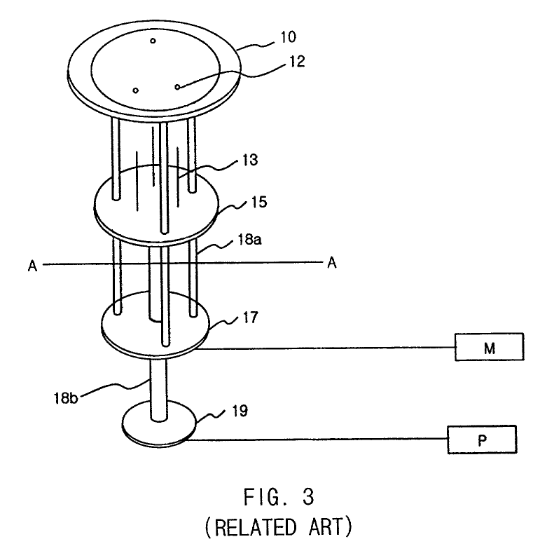

FIG. 4 shows an apparatus for manufacturing a semiconductor device according to the present invention. Here, the same symbol used in FIGS. 1 and 2 is given to the same part as the conventional apparatus of FIGS. 1 and 2. In FIG. 4, the apparatus comprises a processing chamber 1, a table 8, a gas injector 6, and a motor “M”. The processing chamber 1 includes a gate valve 2 and an outlet 4. The upper part of the processing chamber 1 is dome-shaped. The gate valve 2, a path through which a wafer to be handled comes into and goes out of the chamber 1, is formed at a wall of the processing chamber 1. The outlet 4 is connected to a pumping system (not shown) to exhaust air within the processing chamber 1 and to maintain the inside pressure of the processing chamber 1. The gas injector 6, which is connected to the gas supplying system (not shown) on the outside, is disposed on the top of the inner surface of the processing chamber 1. The table 8 includes a susceptor 10 and a susceptor drive plate 17. The susceptor 10 is situated within the processing chamber 1 and holds a wafer 50 thereon. The susceptor 10 has a heater 11, which supplies heat to the wafer 50, inside and has also a plurality of lift pin holes 62, which a plurality of lift pins 60 pass through. On the other hand, the susceptor 10 is connected to the susceptor drive plate 17, which is posited outside of the processing chamber 1, controlled by the motor “M”. Therefore, the susceptor 10 moves upwardly and downwardly by the motor “M”. A bellows 21, which makes the processing chamber 1 airtight, is located between the bottom of the processing chamber land the susceptor drive plate 17.

As stated above, the process for the wafer 50 is executed in the first region 20a inside the processing chamber 1, the upper region over the gate valve 2, and the loading and unloading of the wafer 50 is accomplished in the second region 20b inside the processing chamber 1, the under region of the first region 20a.

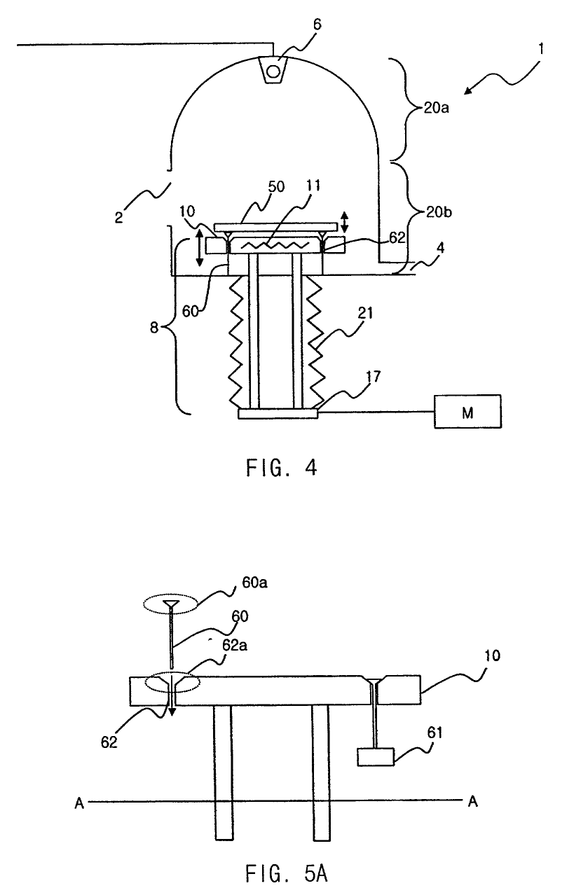

The apparatus of the present invention is explained in more detail with reference to FIGS. 5A and 5B. FIGS. 5A and 5B show structures of the susceptor and the lift pin according to the present invention. In FIGS. 5A and 5B, a line “A-A” indicates the bottom of the processing chamber 1 of FIG. 4. As above-mentioned, the susceptor 10 has the plurality of lift pin holes 62. Each lift pin hole 62 has a hanging part 62a at the upper end of the lift pin hole 62. And each lift pin 60, which passes through each lift pin hole 62, has a hung part 60a at the upper end of the lift pin 60. The upper diameter of the hung part 60a should be shorter than the upper diameter of the hanging part 62a and be longer than the lower diameter of the hanging part 62a in order that the hung part 60a may be hung on the hanging part 62a when the susceptor 10 is situated in the first region 20a of FIG. 4. And a length of the lift pin 60 should be longer than that of the lift pin hole 62 so that the lift pin 60 may be projected up the susceptor 10 when the susceptor 10 is posited in the lowest area of the second region 20b of FIG. 4. The lower part of the lift pin 60 goes through the hanging part 62a and the lower part of the lift pin hole 62 in due order, and so the hung part 60a is hung on the hanging part 62a when the susceptor 10 is located in the first region 20a of FIG. 4. The hanging part 62a and the hung part 60a are either funnel-shaped as shown in FIG. 5A or cylinder-shaped as shown in FIG. 5B. Here, it is desirable that the hanging part 62a has a higher height than the hung part 60a in order to make the hung part 60a posited in hanging part 62a when the process is in progress. Therefore, the wafer 50 of FIG. 4 is situated on only the susceptor 10 in that case.

On the other hand, a support 61 may be combined with the lower end of the lift pin 60. The support 61 prevents the damage of the lift pin 60 occurring by contact of the lower end of the lift pin 60 and the bottom “A-A” of the processing chamber 1 of FIG. 4 when the susceptor 10 is located in the second region 20b of FIG. 4. The support 61 may be combined with the lower end of the lift pin 60 by a screw union. At this time, it is possible that the lower end of the lift pin 60 is an external screw and the support 61 is an internal screw.

As this apparatus has a simple structure, the size of the apparatus can be reduced. Therefore, it is possible to control minutely conditions inside the processing chamber and the extent of producing a bad product decreases. And also a cost of the apparatus decreases.

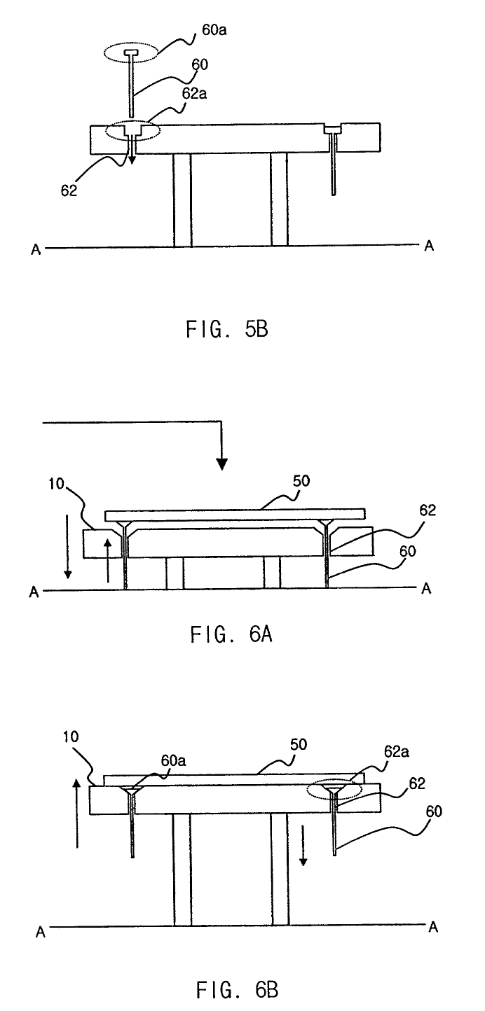

FIGS. 6A and 6B show processes of driving an apparatus according to the present invention. First, as illustrated in FIG. 6A, the susceptor 10 goes down near to the bottom “A-A” of the processing chamber 1 by the motor “M” of FIG. 4. Then, the lift pin 60, which passes through the lift pin hole 62 inside the susceptor 10, contacts the bottom “A-A” of the processing chamber 1, and the lift pin 60 projects up the susceptor 10. Next, the wafer 50 is put on the projecting lift pin 60 through the gate valve 2 of FIG. 4.

Subsequently, as shown in FIG. 6B, the susceptor 10 moves upward by the motor “M”. Then, the lift pin gets to move downward due to the earth's gravity, and the hung part 60a is hung on the hanging part 62a when the susceptor 10 is posited in the first region 20a of FIG. 4. Accordingly, the wafer 50 is located on the susceptor 10, and a depositing or etching process is accomplished.

Next, the susceptor 10 having the wafer 50 thereon descends by the motor “M” and is posited near the bottom “A-A” of the processing chamber 1 as shown in FIG. 6a. At this time, the lift pin 60 contacts the bottom “A-A” of the processing chamber 1 and projects up the susceptor 10. Therefore, the wafer 50 is raised by the lift pin 60 and the wafer 50 is taken out of the processing chamber 1 through the gate valve 2 of FIG. 4.

It will be apparent to those skilled in the art that various modifications and variation can be made in the fabrication and application of the present invention without departing from the spirit or scope of the invention. Thus, it is intended that the present invention cover the modifications and variations of this invention provided they come within the scope of the appended claims and their equivalents.

What is claimed is:

1. An apparatus for manufacturing a semiconductor device, comprising:
a chamber having a gate valve and an outlet;
a susceptor within the chamber to hold a wafer thereon, the susceptor being movable upward and downward, and having a plurality of lift pin holes, each lift pin hole having a hanging part at the upper end; and
a plurality of lift pins passing through the plurality of lift pin holes, each lift pin having a hung part at the upper end and a length of the lift pin being longer than that of the lift pin hole, the upper diameter of the hung part being shorter than the upper diameter of the hanging part and being longer than the lower diameter of the hanging part.

2. The apparatus according to claim 1, wherein the hung part has a lower height than the hanging part.

3. The apparatus according to claim 1, further comprising a support combined with the lower end of the lift pin.

4. The apparatus according to claim 3, wherein the support makes a combination with the lower end of the lift pin by a screw union.

5. The apparatus according to claim 4, wherein the lift pin is an external screw and the support is an internal screw.

6. The apparatus according to claim 1, wherein the hanging part is funnel-shaped.

7. The apparatus according to claim 6, wherein the hung part is funnel-shaped.

8. The apparatus according to claim 1, wherein the hanging part has a shape of cylinder.

9. The apparatus according to claim 8, wherein the hung part has a shape of cylinder.

10. The apparatus according to claim 1, wherein the upper part of the chamber is dome-shaped.

11. The apparatus according to claim 10, further comprising a gas injector at the top of the inner surface of the chamber.

12. The apparatus according to claim 1, further comprising a susceptor drive plate connected to the susceptor, the susceptor drive plate moving by a motor.
